(19) United States
(12) Patent Application Publication
(10) Pub. No.: US 2006/0119911 A1
(43) Pub. Date: Jun. 8, 2006

(54) Image display apparatus, printer, image display method and image display program product

(75) Inventor: Hideyuki Narusawa, Nagano (JP)

Correspondence Address: SUGHRUE MION, PLLC, 2100 PENNSYLVANIA AVENUE, N.W., SUITE 800, WASHINGTON, DC, 20037, US

(73) Assignee: SEIKO EPSON CORPORATION

(21) Appl. No.: 11/192,430

(22) Filed: Jul. 29, 2005

(30) Foreign Application Priority Data
Jul. 29, 2004 (JP) P2004-221939
Jul. 29, 2004 (JP) P2004-221940

(51) Int. Cl. G03F 3/10

(52) U.S. Cl. 358/527

(57) ABSTRACT

An image display device includes an identifier display portion for displaying, on a screen, an identifier corresponding to data of a first kind to which data of a second kind are related and an identifier corresponding to the data of the first kind to which the data of the second kind are not related to be distinguished one from another, a selection accepting portion for accepting a selection of the displayed identifier, and an image display portion for displaying an image on the screen based on the data of the first kind corresponding to the selected identifier and the data of the second kind which are related to the data of the first kind.

### BACKGROUND OF THE INVENTION

The present invention relates to an image display device, a printer, an image display method and an image display program product.

There has been known a printing apparatus for displaying an identifier corresponding to data of a first kind on a screen, accepting the selection of the displayed identifier, and printing an image on a printing medium based on the data of the first kind corresponding to the identifier thus selected. More specifically, the data of the first kind are image data, for example. The identifier is information which can be seen to specify the data of the first kind by a user or information with which the user can grasp contents represented by the data of the first kind, and specifically, is a file name or path name of a file which stores image data or a reduced image represented by the image data if the data of the first kind are the image data, for example.

Some of the printing apparatuses can identify and display the identifier of the data of the first kind to which data of a second kind are related and the identifier of the data of the first kind to which the data of the second kind are not related. More specifically, in the case in which the data of the first kind are image data and the data of the second kind are a processing parameter for designating the trimming region of the image data, and the printing apparatus trims and prints the image data based on the processing parameter, for example, a predetermined mark is given for display to only the identifier corresponding to the image data to which the processing parameter is related. By giving the mark for the display, the user can identify the identifier of the data of the first kind to which the data of the second kind are related and the identifier of the data of the first kind to which the data of the second kind are not related.

In case of the example described above, the user can know, before printing, that a trimmed image is printed by the selection of the identifier having the mark. Contrary to the user's expectation that a whole image represented by image data is printed, therefore, only a part thereof is printed so that the user can be prevented from being confused, for example (see International Laid-Open No. 03/085510 pamphlet).

In the case in which a plurality of files storing the data of the second kind is present, it is not necessary to carry out a relation for each printing if a file of a first kind storing the data of the first kind and a file of a second kind storing the data of the second kind are related to each other, which is convenient. For example, if the identifier of the data of the second kind to be related is stored together with the data of the first kind in the file of the first kind, it is possible to acquire the identifier from the file of the first kind storing the data of the first kind which are selected, thereby uniquely specifying the data of the second kind which are related when the data of the first kind are selected.

When the identifier of the data of the second kind are stored in the file of the first kind, however, it is necessary to open all of the files of the first kind and to decide whether the identifier is included or not in the case in which the names of the files of the first kind to which the data of the second kind are related are to be displayed in a list, for example. In general, a long time is taken for the processing of opening the file. For this reason, the user has to wait for a long time until the list is displayed if a large number of files of the first kind are present.

### SUMMARY OF THE INVENTION

It is an object of the invention to provide an image display device, a printer, an image display method and an image display program product which can rapidly identify, over a screen, whether or not an identifier corresponds to data of a first kind to which data of a second kind are related.

It is another object of the invention to provide an image display device, a printer, an image display method and an image display program product which can ascertain, without printing, which image is based on the data of the first kind and the data of the second kind related to the data of the first kind.

It is a further object of the invention to provide an image display device, a printer, an image display method and an image display program product which can ascertain, in a short time, whether the data of the second kind are related to the data of the first kind or not even if there is a plurality of files of a first kind in the case in which the identifier of the data of the second kind is stored in the file of the first file to relate the data of the second kind to the data of the first kind.

It is a further object of the invention to provide a file processing device, a file processing method and a file processing program product which can be utilized for an image display device, a printer, an image display method and an image display program product.

The invention provides the following structure as a non-restricted example shown in the drawings.

An image display device comprises an identifier display portion for displaying, on a screen, an identifier corresponding to data of a first kind to which data of a second kind are related and an identifier corresponding to the data of the first kind to which the data of the second kind are not related to be distinguished one from another, a selection accepting portion for accepting a selection of the identifier displayed by the identifier display portion, and an image display portion for displaying an image on the screen based on the data of the first kind corresponding to the identifier selected by the selection accepting portion and the data of the second kind which are related to the data of the first kind. According to the image display device, it is possible to identify, over the screen, whether or not the identifier corresponds to the data of the first kind to which the data of the second kind are related. Moreover, the image based on the data of the first kind and the data of the second kind which are related to the data of the first kind is displayed on the screen. Therefore, it is possible to ascertain, without printing, which image is based on the data of the first kind and the data of the second kind which are related to the data of the first kind.

In the image display device, the identifier display portion carries out display by giving a predetermined mark to only the identifier corresponding to the data of the first kind to which the data of the second kind are related, thereby enabling identification. According to the image display device, it is possible to identify, from the mark, whether or not the identifier corresponds to the data of the first kind to which the data of the second kind are related.

In the image display device, the data of the first kind are image data and the data of the second kind are template data for designating a component image to be merged with an optional image, and the image display portion merges the component image designated by the template data with an image represented by the image data and thus carries out display. According to the image display device, it is possible to display an image obtained by merging the component image designated by the template data with the image represented by the image data.

In the image display device, the identifier is an image obtained by reducing an image represented by the data of the first kind. When the reduced image is displayed as the identifier, a user can grasp the image represented by the data of the first kind. Therefore, it is possible to easily carry out a selection.

In the image display device according to the invention, furthermore, the data of the first kind and the data of the second kind are stored in files which are independent of each other.

In the image display device, information capable of specifying a file storing the data of the second kind is stored in the file storing the data of the first kind so that the data of the second kind are related to the data of the first kind.

In the image display device according to the invention, moreover, there is further provided a first instruction accepting portion for accepting an instruction for displaying an image, the image display portion displaying the image when accepting the selection of the identifier by the selection accepting portion and then accepting an instruction for displaying an image by the first instruction accepting portion. According to the image display device, the user can prevent from giving an instruction and carrying out the display if he (she) performs the selection and is not satisfied.

The image display device comprises a retrieving portion for retrieving the data of the first kind from a storage medium, and a correspondence information creating portion for deciding whether or not information specifying the data of the second kind is stored in a file storing the data of the first kind retrieved by the retrieving portion and creating information about a correspondence of the data of the first kind to the data of the second kind based on a result of the decision, the identifier display portion referring to the information about the correspondence. If the information about the correspondence of the data of the first kind and the data of the second kind is created, it is possible to ascertain, in a short time, whether the data of the second kind are related to the data of the first kind by referring to the created information even if a plurality of files stores the data of the first kind.

The image display device comprises a correspondence information creating portion for creating information about a correspondence of the data of the first kind to the data of the second kind when a removable recording medium is connected, the identifier display portion referring to the information about the correspondence. If the information about the correspondence is created when the removable recording medium is connected, it is possible to minimize a possibility that the user might wait when ascertaining whether the data of the second kind are related to the data of the first kind or not.

A printer comprises the image display device, and an image printing portion for printing an image on a printing medium based on the data of the first kind which are selected by the selection accepting portion and to which the data of the second kind are related and the data of the second kind which are related to the data of the first kind. According to the printer, it is possible to ascertain, without printing, which image is based on the data of the first kind and the data of the second kind which are related to the data of the first kind, and furthermore, to print the image.

The printer further comprises a second instruction accepting portion for accepting an instruction for printing an image, the image printing portion printing the image when accepting the selection of the identifier by the selection accepting portion and then accepting the instruction for printing an image by the second instruction accepting portion. According to the printer, the user can prevent from giving an instruction and carrying out the print if he (she) performs the selection and is not satisfied.

An image display method comprises an identifier display step of displaying, on a screen, an identifier corresponding to data of a first kind to which data of a second kind are related and an identifier corresponding to the data of the first kind to which the data of the second kind are not related to be distinguished one from another, a selection accepting step of accepting a selection of the identifier displayed at the identifier display step, and an image display step of displaying an image on the screen based on the data of the first kind corresponding to the identifier selected at the selection accepting step and the data of the second kind which are related to the data of the first kind. According to the image display method, it is possible to ascertain, without printing, which image is based on the data of the first kind and the data of the second kind which are related to the data of the first kind.

An image display program product causes a computer to function as an identifier display portion for displaying, on a screen, an identifier corresponding to data of a first kind to which data of a second kind are related and an identifier corresponding to the data of the first kind to which the data of the second kind are not related to be distinguished one from another, a selection accepting portion for accepting a selection of the identifier displayed by the identifier display portion, and an image display portion for displaying an image on the screen based on the data of the first kind corresponding to the identifier selected by the selection accepting portion and the data of the second kind which are related to the data of the first kind. According to the image display program product, it is possible to ascertain, without printing, which image is based on the data of the first kind and the data of the second kind which are related to the data of the first kind.

A file processing device comprises a first retrieving portion for retrieving data of a first kind from a storage medium, and a correspondence information creating portion for deciding whether or not an identifier of data of a second kind is stored in a file storing the data of the first kind which are retrieved by the first retrieving portion and creating information about a correspondence of the data of the first kind to the data of the second kind based on a result of the decision. By creating the information about the correspondence of the data of the first kind to the data of the second kind through the file processing device, it is possible to ascertain, in a short time whether the data of the second kind are related to the data of the first kind or not by referring to the created information if necessary. According to the file processing device, therefore, it is possible to ascertain, in a short time, whether the data of the second kind are related to the data of the first kind even if a plurality of files stores the data of the first kind.

In the file processing device, the data of the first kind are image data and the data of the second kind are template data for designating a component image to be merged with an optional image.

In the file processing device, the identifier is a predetermined unique code. By using the predetermined unique code as the identifier for the data of the second kind, it is possible to uniquely specify the data of the second kind.

In the file processing device, the predetermined unique code is UUID. The UUID (Universally Unique Identifier) represents a numeric value which has a predetermined bit length that is generated by combining a date, an MAC address of a network interface card and a random number and is guaranteed to non-overlap. By using the UUID as the predetermined unique code, it is possible to uniquely specify the data of the second kind.

In the file processing device, the information causes the data of the first kind to correspond to the presence of the identifier. Depending on the presence of the identifier, it is possible to decide whether the data of the second kind are related to the data of the first kind or not. By referring to the information, therefore, it is possible to ascertain, in a short time, whether the data of the second kind are related to the data of the first kind or not even if a plurality of files stores the data of the first kind.

In the file processing device, the information causes the data of the first kind to correspond to the data of the second kind. According to the file processing device, it is possible to ascertain whether the data of the second kind are related to the data of the first kind or not, and furthermore, which data of the second kind are related if there is the relation.

The file processing device further comprises a second retrieving portion for retrieving the data of the second kind from the storage medium, and the correspondence information creating portion acquires the identifier from the file storing the data of the second kind retrieved by the second retrieving portion and causes the data of the second kind thus retrieved to correspond to the data of the first kind in the file storing the same identifier as the identifier which is acquired.

In the file processing device, the storage medium is a removable memory and the correspondence information creating portion creates the information when the removable memory is connected. By creating the information when the removable memory is attached, it is possible to minimize a possibility that the user might wait for ascertaining whether the data of the second kind are related or not.

An image display device according to the invention comprises the file processing device, an object display portion for referring to the information to distinguish one from another and display, on a screen, an object corresponding to the data of the first kind to which the data of the second kind are related and an object corresponding to the data of the first kind to which the data of the second kind are not related, a selection accepting portion for accepting a selection of the object, thereby accepting a selection of the data of the first kind, and an image display portion for displaying an image on the screen based on the data of the first kind selected by the selection accepting portion and the data of the second kind which are related to the data of the first kind. According to the image display device, it is possible to ascertain, in a short time, whether the data of the second kind are related to the data of the first kind even if a plurality of files stores the data of the first kind.

A printer comprises the file processing device, an object display portion for referring to the information to distinguish one from another and display, on a screen, an object corresponding to the data of the first kind to which the data of the second kind are related and an object corresponding to the data of the first kind to which the data of the second kind are not related, a selection accepting portion for accepting a selection of the object, thereby accepting a selection of the data of the first kind, and an image printing portion for printing an image on a printing medium based on the data of the first kind selected by the selection accepting portion and the data of the second kind which are related to the data of the first kind. When the image is to be printed on the printing medium based on the data of the first kind, it is possible to immediately know whether the printing is to be carried out based on the data of the first kind or both the data of the first kind and the data of the second kind by referring to the created information. Consequently, it is possible to increase a printing speed. In the case in which a plurality of files stores the data of the first kind or the data of the second kind, particularly, the invention is useful.

Each functional portion is implemented by hardware resources having functions specified by structures themselves, hardware resources having functions specified by programs or their combination. Moreover, each functional portion is not restricted to the implementation through hardware resources which are physically independent of each other.

### BRIEF DESCRIPTION OF THE DRAWINGS

In the accompanying drawings,

FIG. 1 is a typical view showing an image selection menu according to a first example of the invention,

FIG. 2(A) is a perspective view showing a printer according to the first example of the invention and (B) is a block diagram,

FIG. 3 is a typical diagram showing a file storing data of a first kind according to the first example of the invention,

FIG. 4 is a typical diagram showing a file storing data of a second kind according to the first example of the invention,

FIG. 5(A) is a typical view for explaining print according to the first example of the invention and (B) is a typical view showing a result of the print,

FIG. 6 is a block diagram showing an image display program according to the first example of the invention,

FIG. 7 is a typical diagram showing a table according to the first example of the invention,

FIG. 8 is a flowchart according to the first example of the invention,

FIGS. 9(A) and (B) are flowcharts according to the first example of the invention,

FIG. 10 is a block diagram showing a file processing program according to the first example of the invention,

FIG. 11 is a flowchart according to the first example of the invention,

FIGS. 12(A) and (B) are typical diagrams showing information according to the first example of the invention,

FIG. 13 is a flowchart according to the first example of the invention,

FIG. 14 is a typical diagram showing information according to the first example of the invention,

FIG. 15 is a typical diagram showing the information according to the first example of the invention,

FIG. 16 is a typical diagram showing information according to a second example of the invention, and

FIG. 17 is a typical diagram showing information according to a third example of the invention.

### DETAILED DESCRIPTION OF THE EXAMPLES

The best mode for carrying out the invention will be described below with reference to examples.

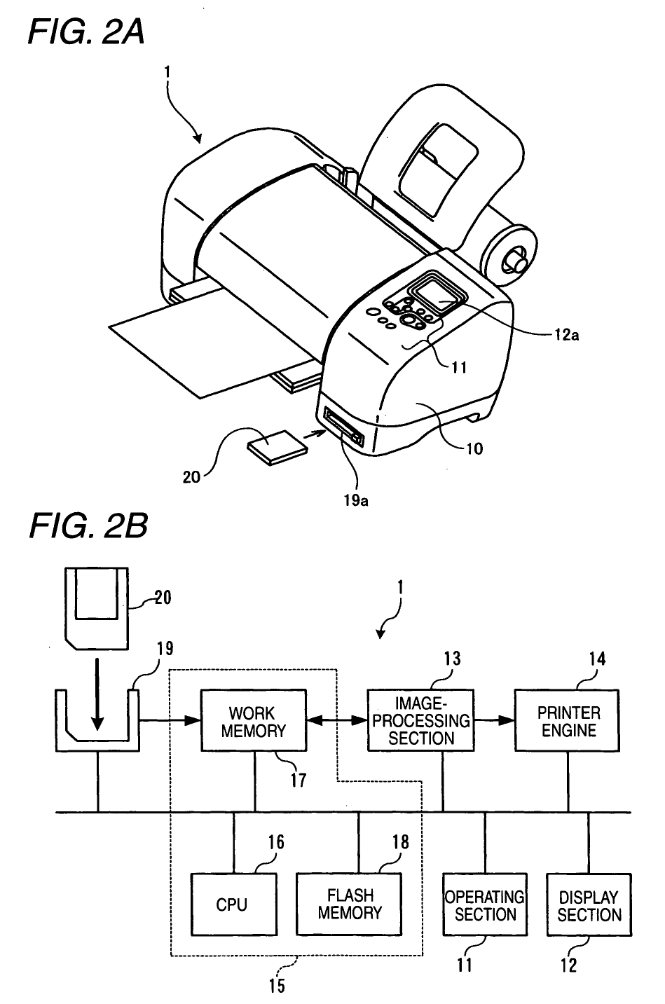

FIG. 2(A) is a perspective view showing the appearance of a printer 1 according to an example of the invention. The printer 1 is of a so-called stand-alone type which does not need a control to be carried out by a personal computer but can singly print an image represented by image data. As shown, an operating portion 11, an LCD 12a, and a card slot 19a are provided in a housing 10 of the printer 1. The operating portion 11 is provided with various operating buttons such as an upper button, a lower button, a determination button, a return button, a print button and a stop button. A menu for carrying out various setting operations is displayed on the screen of the LCD 12a, and the displayed menu is operated by the various operating buttons. The card slot 19a is an opening for connecting a removable memory 20 to a memory read/write portion 19 provided in the housing 10.

FIG. 2(B) is a block diagram showing the hardware configuration of the printer 1.

A control portion 15 includes a CPU 16, a flash memory 18 and a work memory 17. The CPU 16 executes a program stored in the flash memory 18 to control the whole printer 1. Moreover, the CPU 16 executes an image display program stored in the flash memory 18, thereby functioning as an identifier display portion (an object display portion), a selection accepting portion, an image display portion, a first instruction accepting portion, a second instruction accepting portion and an image printing portion. Furthermore, the CPU 16 executes a file processing program stored in the flash memory 18 to also function as a first retrieving portion, a correspondence information creating portion and a second retrieving portion. The file processing program may be a part of an image display program and the image display program may be apart of the file processing program. While a print program is a part of the image display program in the example, they may be prepared separately. These programs may be offered integrally as a printer driver to a user. In the example, the image display device is equivalent to the control portion 15. The flash memory 18 stores various programs and data, and the work memory 17 temporarily stores various programs and data. These various programs and data may be downloaded and input from a predetermined server through a network or may be read and input from a computer readable storage medium such as the removable memory 20.

The memory read/write portion 19 includes a connecting terminal to which the removable memory 20 is removably connected, and a memory controller. The memory read/write portion 19 is controlled by the control portion 15 and functions as a first retrieving portion and a second retrieving portion. In the example, the control portion 15 and the memory read/write portion 19 constitute a file processing device. The removable memory 20 is a non-volatile memory such as a flash memory in which stored contents are not lost even if a power supply is disconnected. The removable memory 20 may be a flexible disk or a CD-ROM. Although the printer 1 according to the example reads/writes the removable memory 20 connected to the memory read/write portion 19, moreover, a hard disk provided in an external storage device connected to the network may be read and written via the network.

A display portion 12 to be an image display portion includes a display controller and the LCD 12a. The display controller is controlled by the control portion 15 to display a menu and a variety of information on the LCD 12a.

An image processing portion 13 to be an image printing portion is an ASIC for creating print data based on image data stored in the work memory 17. More specifically, the image processing portion 13 executes, in cooperation with the control portion 15, the expansion of image data compressed in JPEG standards, the conversion of the color space of the expanded image data, a gamma correction, a color balance regulation, a sharpness regulation, a contrast regulation, a resolution conversion for converting the resolution of image data into a print resolution, a binary processing of changing image data into a binary, and an interlace processing of rearranging the binary image data in such order as to be transferred to a printer engine 14, thereby generating print data, for example. Whether these processings are carried out by the control portion 15 or the image processing portion 13 is a design matter which can be selected properly.

The printer engine 14 to be an image printing portion prints an image on a printing medium such as a paper based on the print data generated by the image processing portion 13. The printer engine 14 is constituted by a carriage for mounting a printing head, a driving mechanism for reciprocating the carriage, and a delivery mechanism for delivering a printing medium. They are controlled by the control portion 15. A plurality of ink tanks for storing inks to be discharged from the printing head is mounted for respective colors on the carriage in addition to the printing head. The printer engine 14 may print an image by a laser method or a dot impact method, for example.

Next, description will be given to a file storing data of a first kind. In the example, description will be given by taking, as an example, image data to be the data of the first kind and an image file storing the image data to be the file of the first kind. As will be described below, temperate data to be the data of the second kind and a template file to be the file of the second kind for storing the data of the second kind will be taken as an example.

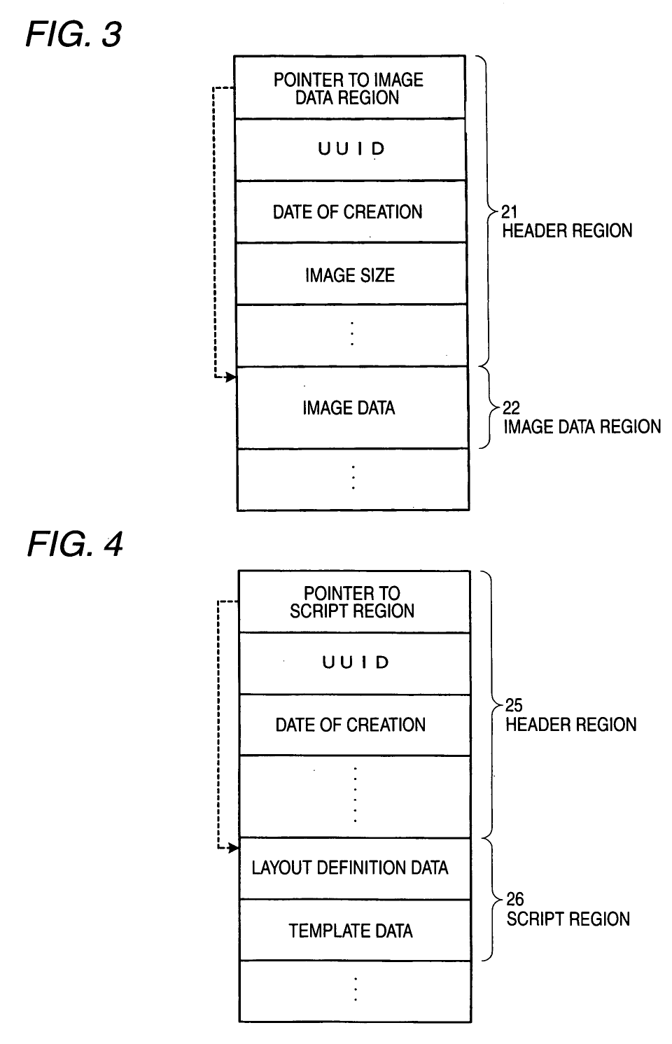

FIG. 3 is a typical diagram showing the file structure of a file for storing the image data to be the data of the first kind (which will be hereinafter referred to as an “image file”). The image file includes a header region 21 and an image data Region 22. The header region 21 is a region for recording header information such as a pointer indicative of the head address of the image data region 22, UUID to be information capable of specifying a file storing the data of the second kind, and furthermore, a date of creation and an image size. The UUID serves to relate the template data to the image data. For example, the UUID of the template file storing the template data designated when photographing is carried out by means of a digital camera is stored in the header region 21 of the image file storing the image data. Consequently, the template data are related to the image data. In the case in which the UUID is not stored, it is implied that the template data are not related to the image data. The UUID is a value guaranteed to non-overlap. Therefore, it is possible to uniquely specify the file storing the data of the second kind by using the UUID. In the case in which the file storing the data of the second kind can be specified uniquely in a file name or a path name, the file name or the path name may be stored in place of the UUID. In the case in which the UUID is not stored, it is implied that the data of the second kind are not related to the image data. The image data region 22 is a region for recording the image data. In display, it is possible to specify the head address of the image data region 22 by reading the pointer from the header region 21. Thus, it is possible to read the image data. It is sufficient that the image file has a file format capable of storing the UUID, and a TIFF format and an Exif format can be used as the file format of the image file, for example. In the example, description will be given by taking an image file in the Exif format (which will be hereinafter referred to as an “Exif file”) as an example. It is possible to properly select what kind of image file is set to be the file of the first kind. For example, an image file in the TIFF format may be set to be the file of the first kind in addition to the Exif file.

Next, description will be given to a file storing the data of the second kind. In the example, description will be given by taking the template data as an example of the data of the second kind.

FIG. 4 is a typical diagram showing the file structure of a file storing the template data to be the data of the second kind (which will be hereafter referred to as a “template file”). The template file includes a header region 25 and a script region 26. The header region 25 is a region for recording header information such as a pointer indicative of the head address of the script region 26, UUID given to the template file, and furthermore, a date of creation. The script region 26 is a region for recording layout definition data and template data to be the data of the second kind. The template data serve to designate a component image to be merged with an image represented by optional image data, and more specifically, include a file name or path name of a component image file storing component image data representing a component image. The template data may be URL for the component image file. The layout definition data serve to define a display reproducing layout for image data, and more specifically, include a size of a print paper (for example, “postcard”), information for defining the direction of the print paper (for example, “vertical”), information for defining a frame (an image frame) to arrange an image represented by the image data stored in the Exif file (for example, upper right coordinates “(x1, y1)” and lower left coordinates “(x2, Y2)” in the frame), and information for defining a frame (a component image frame) to arrange a component image represented by the component image data stored in the component image file (for example, upper right coordinates “(x3, y3)” and lower left coordinates “(x4, Y4)” in the frame). While the layout definition data are also stored in the template file in the example, they do not need to be stored if unnecessary. Although both the template data and the layout definition data are stored in the file of the second kind in the example, the file of the second kind may store only one of them. While the file name or path name of the component image file is stored in the file of the second kind in the example, moreover, the component image data may be stored in the file of the second kind itself. The layout definition data and the template data are formed in a script.

The template file is selected by a user when an object is to be photographed by means of a digital camera, for example. When the object is photographed by means of the digital camera to create image data, the UUID stored in the selected template file and the created image data are stored in the same Exif file. Consequently, the template data are related to the image data.

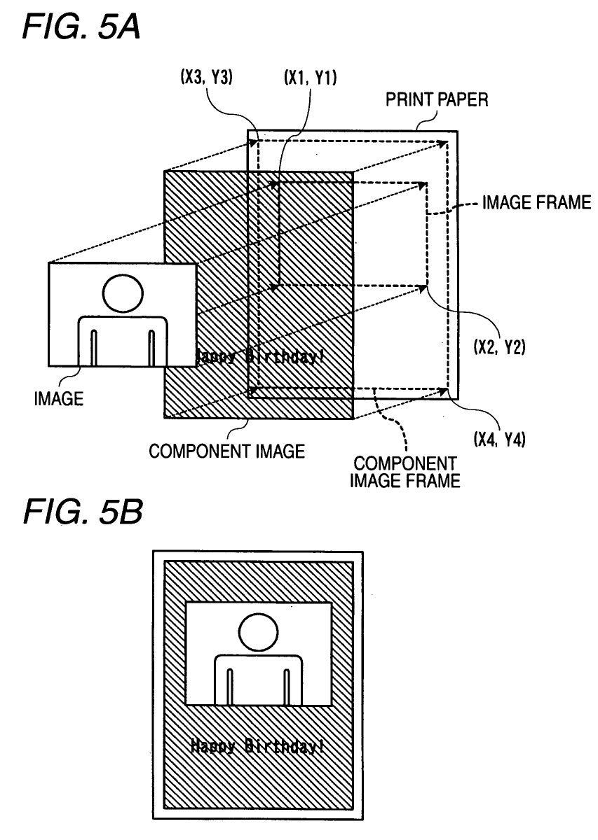

FIG. 5(A) is a typical view for explaining display/print using the template file, and FIG. 5(B) is a typical view showing a result thereof. The image represented by the image data stored in the Exif file and the component image represented by the component image data stored in the component image file are merged and displayed/printed as shown in accordance with a reproducing layout defined by the template file.

Next, an image display program will be described.

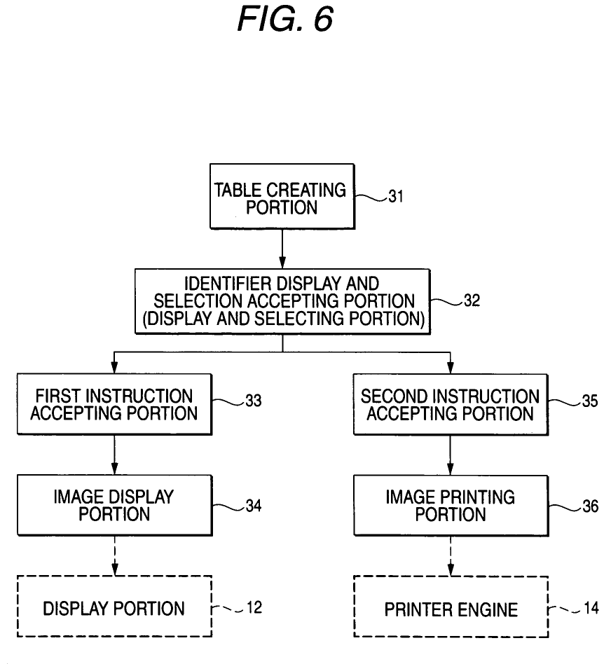

FIG. 6 is a block diagram showing the logical structure of the image display program. The image display program includes a table creating portion 31, an identifier display and selection accepting portion 32 (which will be hereinafter referred to as a “display and selecting portion”), a first instruction accepting portion 33, an image display portion 34, a second instruction accepting portion 35, and an image printing portion 36.

The table creating portion 31 serves to create a table for causing the Exif file to correspond to the template file.

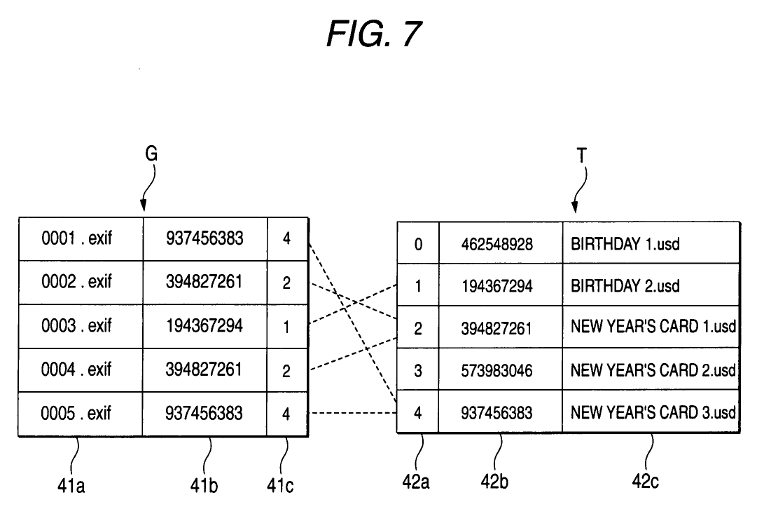

FIG. 7 is a typical diagram showing an example of the table for causing the Exif file to correspond to the template file. As shown, the table is divided into an image table G and a template table T.

The image table G is constituted by a file information column 41a for storing information capable of uniquely specifying the Exif file, a UUID column 41b for storing the UUID included in the Exif file, and a template ID column 41c for storing a template ID. More specifically, the information capable of uniquely specifying the Exif file is the file name or path name of the Exif file, for example. The template ID is a code for causing the record (image record) of the image table G to correspond to the record (template record) of the template table T. When the removable memory 20 is connected to the memory read/write portion 19, the table creating portion 31 retrieves the Exif file from the removable memory 20 thus connected, thereby creating the image table G. By creating the image table G, it is possible to ascertain, in a short time, whether the template file is related to each of Exif files or not if there are the Exif files.

The template table T is constituted by a template ID column 42a for storing the template ID, a UUID column 42b for storing UUID included in the template file, and a file information column 42c for storing information capable of uniquely specifying the template file. More specifically, the information capable of uniquely specifying the template file is the file name or path name of the template file, for example. When the record is added to the template table T, the template ID for uniquely identifying the record is generated and stored in the template ID column 42a. The template ID of the template record having the same UUID as the image record in the template table T is stored in the template ID column 41c of the image record. Consequently, the image record and the template record are caused to correspond to each other through the template ID. When the removable memory 20 is connected to the memory read/write portion 19, the table creating portion 31 retrieves the template file from the connected removable memory 20, thereby creating the template table T. By creating the template table T, it is possible to specify the template file related to the Exif file in a short time.

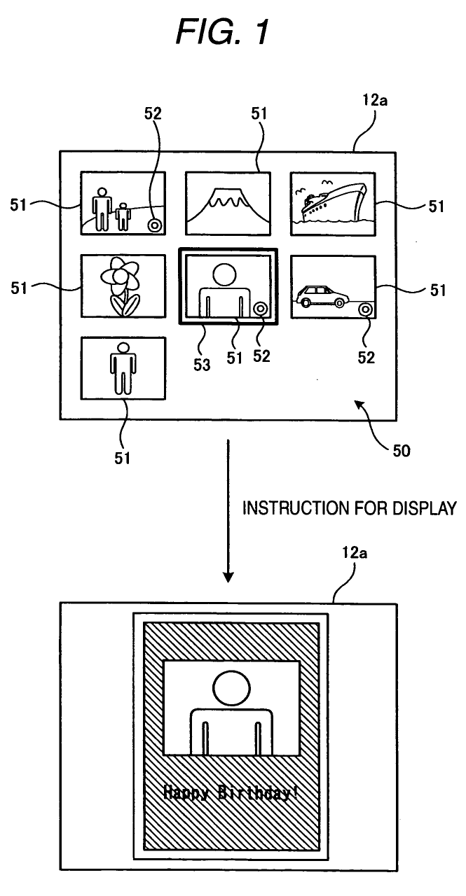

The display and selecting portion 32 displays an image selection menu 50 shown in FIG. 1 on the LCD 12a and accepts the selection of an identifier. A reduced image 51 of an image represented by the image data stored in the Exif file recorded on the removable memory 20 is listed and displayed on the image selection menu 50. The reduced image 51 is equivalent to the identifier. For example, the file name or path name of the Exif file may be displayed as the identifier. When the reduced image 51 is displayed as the identifier, the user can grasp the image represented by the image data, thereby carrying out the selection easily.

The reduced image 51 having a mark 52 displayed thereon in the image selection menu 50 indicates that the template data are related to the image data corresponding to the reduced image 51. To the contrary, the reduced image 51 having no mark 52 displayed thereon implies that the template data are not related to corresponding image data. The display and selecting portion 32 determines which reduced image 51 has the mark 52 displayed thereon by referring to the image table G when displaying the image selection menu 50. By referring to the image table G, it is possible to decide, in a short time, whether the template data are related to the image data or not when the image selection menu 50 is called, and to display the image selection menu 50 in a short time. Even if there are a plurality of image data, accordingly, the user can ascertain, in a short time, whether the template data are related to the image data or not. When the mark 52 is displayed, the user can identify, over the screen, whether the template data are related to the image data or not. Therefore, it is possible to prevent the user from being confused due to the print of a composite image which is carried out against the intention of the user or the print of a non-composite image. When the relation of the template data is indicated as the mark 52, moreover, it is possible to simplify the processing. For example, referring to the image data to which the template data are related, it is also possible to actually generate a composite image based on the template data and to display the reduced image 51 of the composite image which is generated, thereby carrying out the display to distinguish whether the template data are related to the image data or not. In that case, however, the composite image is to be generated. Consequently, the amount of the processing is increased. By carrying out the identification through the mark 52, therefore, it is possible to simplify the processing. Even if the throughput of the CPU 16 is low, the image selection menu 50 can be displayed in a short time.

When the user operates the button of the operating portion 11 to input the direction and amount of movement of a cursor 53, the display and selecting portion 32 accepts a signal input from the operating portion 11 and moves the cursor 53 in response to the input signal thus accepted. The reduced image 51 designated by the cursor 53 after the movement is the reduced image 51 which is selected. Consequently, the user can select the reduced image 51 which is intended. The “accept the selection” implies that the input signal for moving the cursor 53 is accepted and the cursor 53 is moved to a position corresponding to the input signal thus accepted in the example. While the reduced images 51 are listed and displayed in the example, the reduced images 51 may be displayed one by one in order in a larger size than that of FIG. 1 every time a predetermined operating button is pressed down, and the reduced image 51 thus displayed may be set to be the reduced image 51 which is selected.

The first instruction accepting portion 33 accepts an instruction for displaying an image. More specifically, the user presses down the determination button of the operating portion 11 to give an instruction for display in a state in which the reduced image 51 to be intended is selected by the image selection menu 50, for example. By accepting an input signal from the determination button, the first instruction accepting portion 33 accepts an instruction for displaying an image. When the instruction is accepted, the first instruction accepting portion 33 gives the image display portion 34 an instruction for displaying an image.

The image display portion 34 displays an image on the LCD 12a based on the image data corresponding to the reduced image 51 which is selected. More specifically, when the image display portion 34 receives an instruction for displaying an image from the first instruction accepting portion 33, it decides whether the template data are related to the corresponding image data or not by referring to the image table G. More specifically, the decision is made depending on whether or not the file name or path name of the Exif file storing the image data is present in the image table G. In the case in which the template data are related, the file name or path name of the template file corresponding to the Exif file storing the image data is acquired from the template table T and a composite image is generated based on the image data and the template data stored in the template file specified by the file name or the path name which is acquired, and the display portion 12 is controlled to display a composite image on the LCD 12a as shown in FIG. 1. In the case in which the template data are not related, only an image represented by the image data is displayed.

The second instruction accepting portion 35 accepts an instruction for printing an image. More specifically, the user presses down the print button of the operating portion 11 to given an instruction for print in a state in which the reduced image 51 is selected through the image selection menu 50, for example. The second instruction accepting portion 35 accepts an input signal from the print button, thereby accepting an instruction for printing an image. When accepting the instruction, the second instruction accepting portion 35 gives an instruction for printing an image to the image printing portion 36.

The image printing portion 36 prints an image on a printing medium based on the image data corresponding to the reduced image 51 which is selected. More specifically, when receiving an instruction for printing an image from the second instruction accepting portion 35, the image printing portion 36 decides whether the template data are related to the image data or not in the same manner as the image display portion 34. If the template data are related, a composite image is generated based on the image data and the template data related to the image data in the same manner as the image display portion 34 and the composite image thus generated is subjected to various processing in cooperation with the image processing portion 13, and the printer engine 14 is controlled to print the composite image on the printing medium. If the template data are not related, only an image represented by the image data is printed.

Next, description will be given to the flow of the processing of the printer 1.

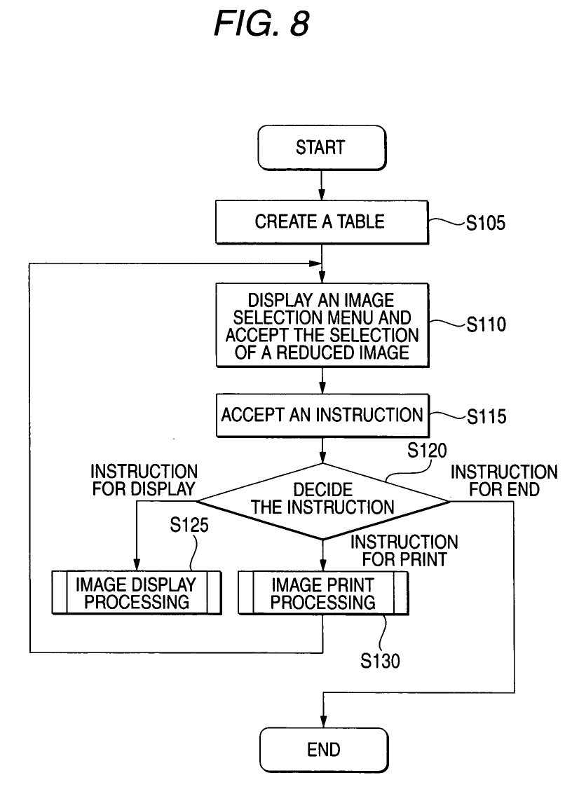

FIG. 8 is a flowchart showing the flow of the processing of the printer 1.

At S105, the image table G and the template table T are created.

At S110, the selection of the reduced image 51 is accepted. More specifically, when the user carries out a predetermined operation, the printer 1 displays the image selection menu 50 on the LCD 12a. The user operates the operating portion 11 to select the reduced image 51 which is intended.

At S115, an instruction for displaying an image, an instruction for printing an image or an instruction for ending a processing is accepted.

At S120, the processing is branched in accordance with the accepted instruction. More specifically, the processing proceeds to S125 if the instruction for displaying an image (an instruction for display) is accepted, and proceeds to S130 if the instruction for printing an image (an instruction for print) is accepted. If the instruction for ending a processing (an instruction for end) is accepted, the processing is ended.

At the S125, an image display processing is executed.

At the S130, an image print processing is executed.

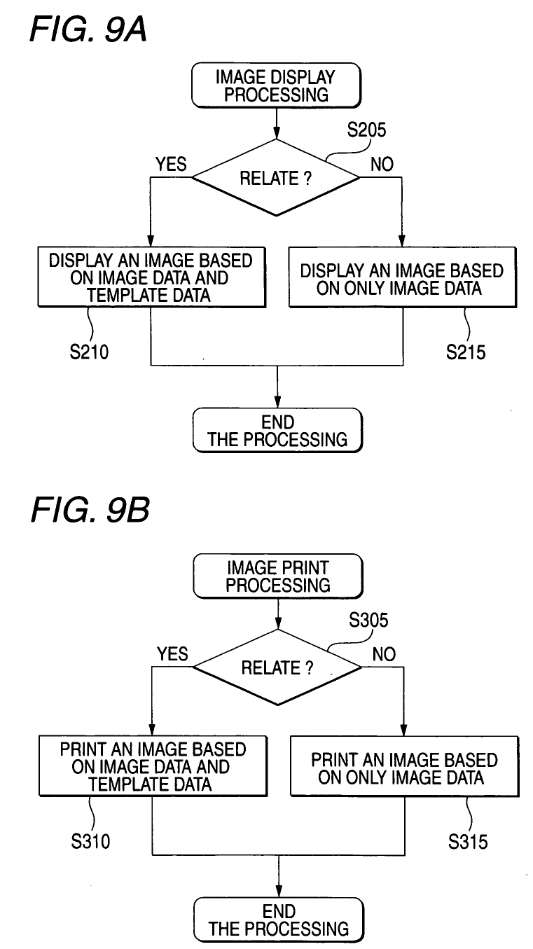

FIG. 9(A) is a flowchart showing the flow of the image display processing in the S125 and FIG. 9(B) is a flowchart showing the flow of the image print processing in the S130.

First of all, the flow of the image display processing will be described.

At S205, it is decided whether or not the template file is related to the Exif file corresponding to the reduced image 51 which is selected at the S110 shown in FIG. 8 by referring to the image table G. The processing proceeds to S210 if the template file is related, and proceeds to S215 if the template file is not related.

At the S210, the file name or path name of the template file thus related is acquired from the template table T. Next, a composite image is displayed on the LCD 12a based on the Exif file corresponding to the reduced image 51 which is selected and the template file.

At the S215, only an image represented by the image data stored in the Exif file corresponding to the reduced image 51 which is selected is displayed on the LCD 12a.

Subsequently, the flow of the image print processing will be described.

At S305, it is decided whether or not the template file is related to the Exif file corresponding to the reduced image 51 which is selected at the S110 shown in FIG. 8 by referring to the image table G. The processing proceeds to S310 if the template file is related, and proceeds to S315 if the template file is not related.

At the S310, the file name or path name of the template file which is related is acquired from the template table T. Next, a composite image is printed on the printing medium based on the Exif file corresponding to the reduced image 51 which is selected and the template file.

At the S315, only an image represented by the image data stored in the Exif file corresponding to the reduced image 51 which is selected is printed on the printing medium.

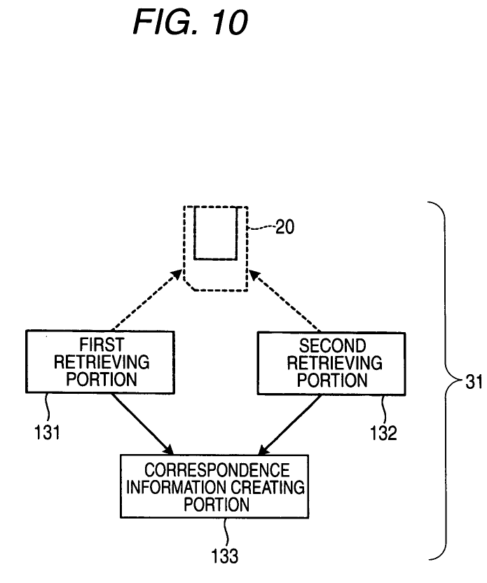

Next, description will be given to an example of a method of creating the table described with reference to FIG. 7, that is, a table for relating the image data (the data of the first kind) to the template data (the data of the second kind). The CPU 16 executes a file processing program stored in the flash memory 18, thereby functions as the table creating portion 31 to create the table. The table creating portion 31 includes a first retrieving portion 131, a second retrieving portion 132 and a correspondence information creating portion 133 as shown in FIG. 10.

The first retrieving portion 131 retrieves the Exif file from the removable memory 20. More specifically, the first retrieving portion 131 searches for an image file having an extension of “.exif” following a lower directory in order by setting the predetermined directory of the removable memory 20 as a starting point. When the image file having the extension of “.exif” is found, the first retrieving portion 131 outputs the path of the Exif file to the correspondence information creating portion 133. This is repeated for all of the lower directories to retrieve all of the Exif files stored under the directory to be the starting point.

The second retrieving portion 132 also retrieves the template file from the removable memory 20. More specifically, the second retrieving portion 132 follows the lower directories in order by setting the predetermined directory of the removable memory 20 to be the starting point, thereby finding a file having an extension of “.usd” assigned to the template file. When the file having the extension of “.usd” is found, the second retrieving portion 132 outputs the path of the file to the correspondence information creating portion 133. This is repeated for all of the lower directories to retrieve all of the template files stored under the directory to be the starting point.

The correspondence information creating portion 133 decides whether the UUID is included in the Exif file retrieved by the first retrieving portion 131 or not, and creates information about the correspondence of the Exif file to the template file, more specifically, a table for causing the Exif file to correspond to the template file based on the result of the decision. The “information about the correspondence” is equivalent to a table created by the correspondence information creating portion 133.

Next, the flow of the processing of the file processing program will be described. In a first example, when the removable memory 20 is connected, a table is created. If the table is not created when it is to be ascertained whether the template data are related to the image data or not, the user is caused to wait until the table is created. Accordingly, it is desirable that the table should be created at a time which is as early as possible to minimize the possibility that the user might wait, that is, when the removable memory 20 is connected.

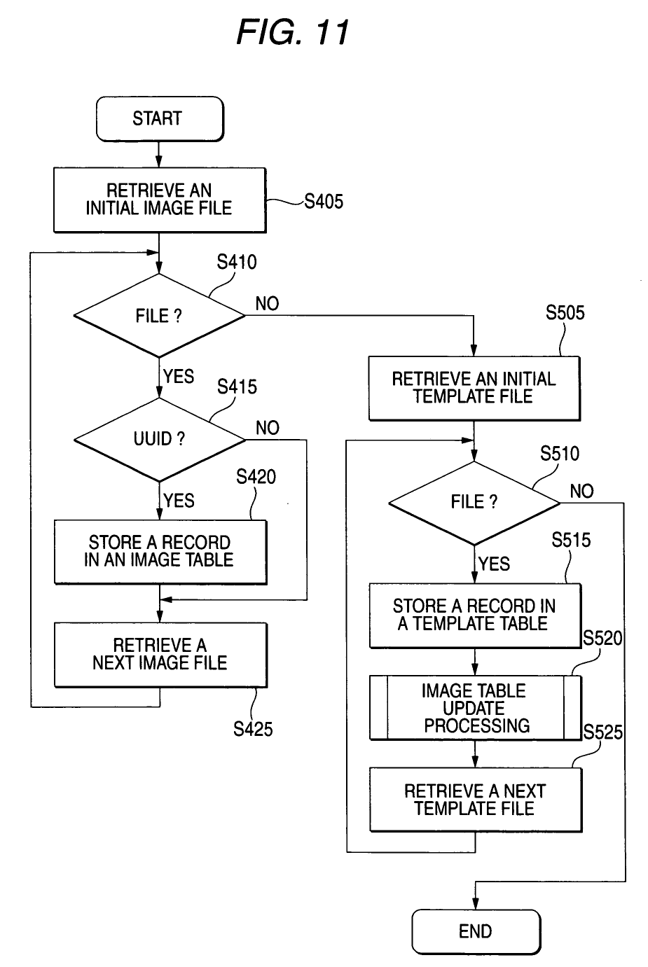

FIG. 11 is a flowchart showing the flow of the processing of the file processing program.

At S405, an initial Exif file is retrieved. More specifically, when the user connects the removable memory 20 to the memory read/write portion 19, a predetermined interruption is generated on an OS. When the interruption is generated, the OS calls the correspondence information creating portion 133. When the correspondence information creating portion 133 is called, it gives an instruction for execution to the first retrieving portion 131. When receiving the instruction for execution, the first retrieving portion 131 follows the lower directories in order by setting the predetermined directory to be the starting point, thereby repeating the retrieval until the initial Exif file is found or a last directory is reached.

At S410, the processing proceeds to S415 when the first retrieving portion 131 finds the Exif file, and proceeds to S505 when the first retrieving portion 131 does not find the Exif file.

At the S415, the correspondence information creating portion 133 decides whether or not the UUID is included in the Exif file thus found. More specifically, the first retrieving portion 131 outputs the path of the found Exif file to the correspondence information creating portion 133. The correspondence information creating portion 133 reads the Exif file specified by the path output from the first retrieving portion 131 and decides whether the UUID is recorded or not. The processing proceeds to S420 when the UUID is recorded, and proceeds to S425 when the UUID is not recorded.

At the S420, the correspondence information creating portion 133 stores the file information of the Exif file and the UUID in an image table which will be described below.

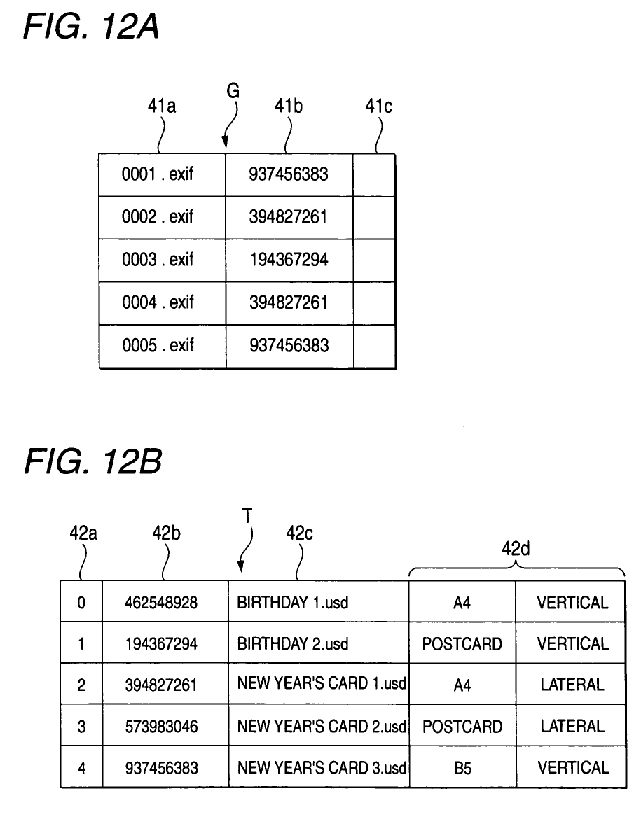

FIG. 12(A) is a typical diagram showing an example of the image table. The image table G is constituted by the file information column 41a for storing information capable of uniquely specifying the Exif file, the UUID column 41b for storing the UUID included in the Exif file, and the template ID column 41c for storing a template ID. More specifically, the information capable of uniquely specifying the Exif file is the file name or path name of the Exif file, for example. The template ID is a code for causing the record of the image table G to correspond to that of the template table which will be described below. At this time, the template ID has not been assigned yet.

At the S425, the correspondence information creating portion 133 gives the first retrieving portion 131 an instruction for retrieving the next Exif file.

By repeating the processing described above, all of the Exif files stored in the lower directories are retrieved. When all of the Exif files are retrieved, the Exif file is not found but the last directory is reached in the retrieval at the next S425. It is decided that the Exif file is not found at the S410 so that the processing proceeds to the S505.

At the S505, the initial template file is retrieved. More specifically, the correspondence information creating portion 133 gives an instruction for execution to the second retrieving portion 132. When receiving the instruction for execution, the second retrieving portion 132 follows the lower directories in order by setting the predetermined directory to be a starting point, thereby repeating the retrieval until the initial template file is found or the last directory is reached.

At S510, the second retrieving portion 132 causes the processing to proceed to S515 when the template file is found, and ends the processing when the template file is not found.

At the S515, the correspondence information creating portion 133 stores a template ID, the file information of a template file, UUID, and information about a display layout in a template table which will be described below.

FIG. 12(B) is a typical diagram showing an example of the template table. The template table T is constituted by the template ID column 42a for storing a template ID, the UUID column 42b for storing UUID included in the template file, the file information column 42c for storing information capable of uniquely specifying the template file, and a display layout column 42d for storing information about a display layout included in the template file. More specifically, the information capable of uniquely specifying the template file is the file name or path name of the template file, for example. More specifically, information about a display layout includes the size and direction of a paper. The information to be stored in the display layout column 42d can be selected properly. When the information about the display layout is stored, it is possible to know a template file to be printed on a print paper having an A4 size in a short time by referring to the template table T if necessary, for example. When a record is added to the template table T, a template ID for uniquely identifying the record is generated and stored in the template ID column 42a. When the template table T is created, it is possible to ascertain which template file is related in the case in which the template file is related to the Exif file. When the Exif file to which the template file is related is selected, therefore, it is possible to specify the template file related to the Exif file in a short time by referring to the template table T. Thus, it is possible to shorten a time required from the selection of the Exif file to the start of the print.

At S520, the correspondence information creating portion 133 updates the template ID column 41c of the image table G. The details of the processing at the S520 will be described below.

At S525, the correspondence information creating portion 133 gives the second retrieving portion 132 an instruction for retrieving the next template file.

By repeating the processing described above, all of the template files stored in the lower directories are retrieved. When all of the template files are retrieved, the template file is not found but the last directory is reached in the retrieval at the next S525. It is decided that the template file is not found at the S510, and the processing is ended.

Next, the details of the processing at the S520 will be described.

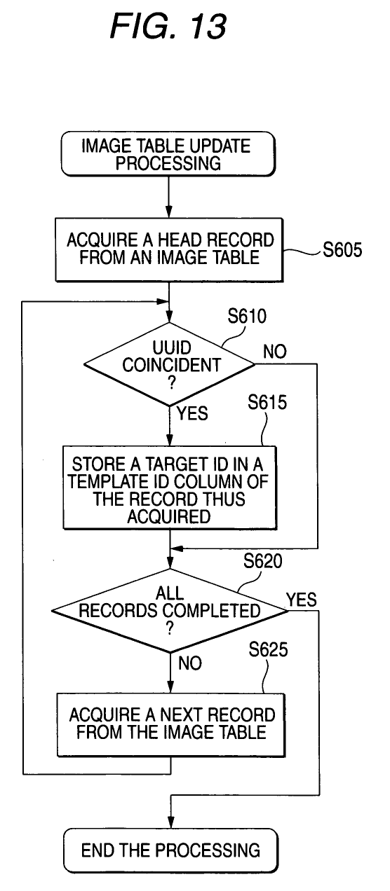

FIG. 13 is a flowchart showing the flow of the processing at the S520.

At S605, a head record is acquired from the image table G.

At S610, it is decided whether or not the UUID stored in the record thus acquired is coincident with the UUID of the template file found at the S505 or S525. The processing proceeds to S615 if they are coincident with each other, and proceeds to S620 if they are not coincident with each other.

At the S615, a target template ID is stored in the template ID column 41c of the acquired record. The target template ID implies a template ID given to a record corresponding to the template file found at the S505 or S525.

At the S620, it is decided whether the selection of all of the records stored in the image table G is completed or not. If the selection is not completed, the processing proceeds to S625 and the processing is repeated until the selection of all of the records is completed. If the selection is completed, the processing is ended.

As described above, the same template ID as the template file is stored in a record having the same UUID as that of the template file found at the S505 or S525 in the image table G.

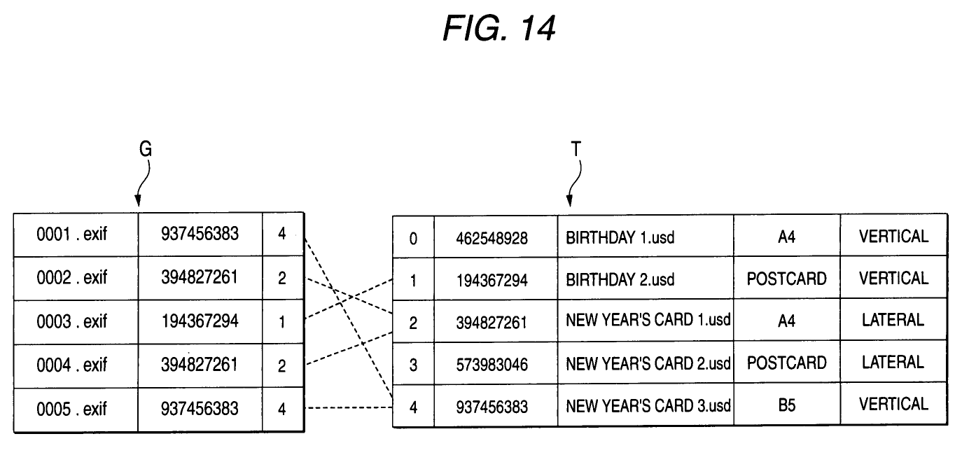

FIG. 14 is a typical diagram showing a table created finally. As shown, the record of the image table G and that of the template table T are caused to correspond to each other through a template ID. The image file is caused to correspond to the template file which is related. Therefore, it is possible to ascertain which template file is related to the image file by referring to the image table G and the template table T. As is apparent from FIG. 14, the record can also be caused to correspond by setting the UUID to be a key.

The table shown in FIG. 14 includes the display layout column 42d. If the layout definition data do not need to be related to the image data, the display layout column 42d may be omitted as shown in FIG. 7.

Referring to the printer 1 according to the first example of the invention described above, a table for causing the Exif file stored in the removable memory 20 to correspond to the template file related to the Exif file is created. When the image selection menu 50 is called, therefore, it is possible to ascertain, in a short time, whether the template file is related to each Exif file or not by referring to the created table. Thus, it is possible to display the image selection menu 50 in a short time. Even if there is a plurality of image files, accordingly, the user can ascertain, in a short time, whether the template file is related to each image file or not.

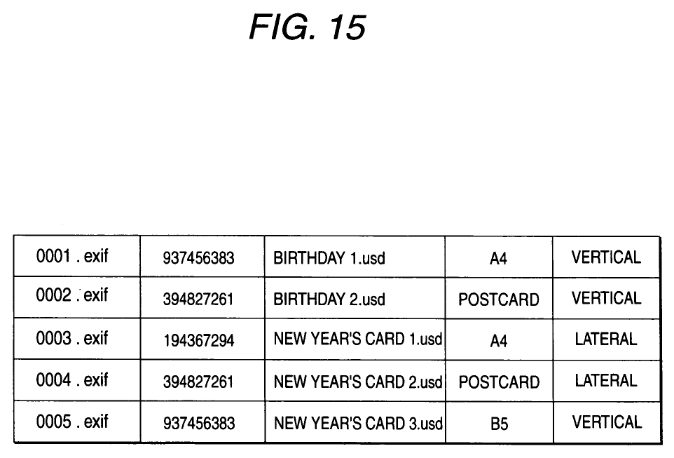

While the information is divided into the image table G and the template table T in the first example, one table may be created as shown in FIG. 15. In this case, the template ID column is not required.

While the description has been given to the image display device comprising the file processing device by taking the printer 1 as an example in the first example, moreover, it is also possible to provide the file processing device in a personal computer, a digital camera, a cell phone or a PDA.

### SECOND EXAMPLE

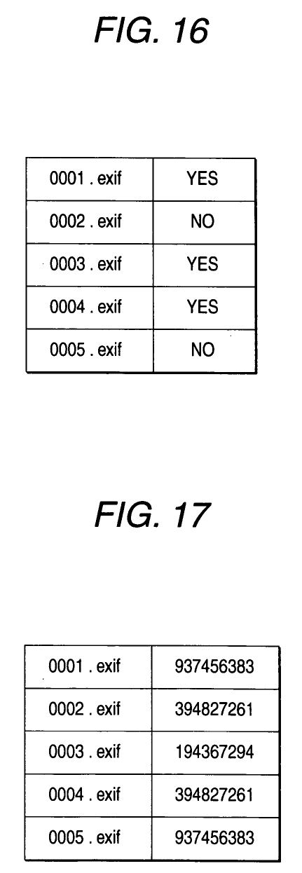

FIG. 16 is a typical diagram showing “information about a correspondence” according to a second example. The “information about a correspondence” according to the second example is a table for causing an image file to correspond to the presence of an identifier as shown in the drawing. If the presence of the identifier is caused to correspond, it is possible to decide whether template data are related to image data or not. It is sufficient that whether template data are related to the image data can be ascertained in a short time. In the case in which it is not necessary to ascertain which template data are related, it is sufficient that the table shown in FIG. 16 is created. By retrieving only an image file, it is possible to create the table shown in FIG. 16. Since a template file does not need to be retrieved, the creation can be carried out in a short time.

### THIRD EXAMPLE

FIG. 17 is a typical diagram showing “information about a correspondence” according to a third example. The “information about a correspondence” according to the third example is a table for causing an image file and an identifier to correspond to each other as shown in the drawing. It is also possible to create the table according to the third example without retrieving a template file. Therefore, the creation can be carried out in a short time. In the third example, the identifier of the template file is caused to correspond. When image data are to be printed based on template data, therefore, it is possible to specify the template data corresponding to the image data in a shorter time than that in the second example.

According to the printer 1 in accordance with the examples of the invention described above, the display is carried out with the mark 52 given to the reduced image 51 corresponding to the image data to which the template data are related. Therefore, it is possible to identify, over the LCD 12a, whether or not the reduced image 51 corresponds to the image data to which the template data are related. When the reduced image 51 having the mark 52 is selected to give an instruction for display, an image based on the image data corresponding to the reduced image 51 which is selected and the template data related to the image data is displayed on the LCD 12a. Therefore, a user can ascertain which image is based on the image data corresponding to the reduced image 51 which is selected and the template data related to the image data without carrying out print. By hindering the user from giving the instruction for print when he (she) is not satisfied with the displayed image, consequently, it is possible to prevent a printing medium or an ink from being wasted or a time required for printing from being wasted as a result.

While the description has been given by taking the template data as an example of the data of the second kind in the examples, the data of the second kind may be layout definition data. Moreover, the data of the second kind may be a processing parameter for designating a trimming region or a processing parameter related to various other image processings to be carried out over the data of the first kind. In case of the processing parameter, it is desirable that the mark 52 corresponding to the contents of the processing should be displayed.

While the template data according to the examples designate the component image data through the file name or path name of the component image file, furthermore, the template data themselves may be the component image data. More specifically, the component image file itself may be treated as the template file.

While it is possible to distinguish by giving the mark 52 to the reduced image 51 in the examples, furthermore, it may be possible to distinguish by turning on/off the reduced image 51 corresponding to the image data to which the template data are related or displaying a frame around the reduced image 51, for example.

While the UUID of the template file is stored in the Exif file to relate the template data to the image data in the examples, moreover, the image data and the template data may be related to each other by another method. More specifically, a file for relating the Exif file to the template file (which will be hereinafter referred to as a “relating file”) is prepared separately and a file name excluding the extension of the relating file may be set to be the same as that of the image file and the file name or path name of the template file may be stored in the relating file, for example. When the reduced image 51 is selected, consequently, a relating file having the same name as that of the Exif file storing the image data corresponding to the reduced image 51 is retrieved and the file name or path name of the template file is acquired from the relating file which is retrieved so that the template data can be specified.

While the description has been given by taking, as an example, the case in which the image data and the template data are stored in independent files respectively and the UUID of the template file is stored in the image file to relate the image data to the template data in the examples, furthermore, the image data and the template data may be stored in the same file to be related to each other.

While the description has been given by taking, as an example, the case in which the image display device is provided in the printer 1 in the examples, moreover, it is also possible to provide an image display device in a personal computer, a digital camera, a cell phone or a PDA.

1. An image display device comprising:
an identifier display portion for displaying, on a screen, an identifier corresponding to data of a first kind to which data of a second kind are related and an identifier corresponding to the data of the first kind to which the data of the second kind are not related to be distinguished one from another;
a selection accepting portion for accepting a selection of the identifier displayed by the identifier display portion; and
an image display portion for displaying an image on the screen based on the data of the first kind corresponding to the identifier selected by the selection accepting portion and the data of the second kind which are related to the data of the first kind.

2. The image display device according to claim 1, wherein the identifier display portion carries out display by giving a predetermined mark to only the identifier corresponding to the data of the first kind to which the data of the second kind are related, thereby enabling identification.

3. The image display device according to claim 1, wherein the data of the first kind are image data and the data of the second kind are template data for designating a component image to be merged with an optional image, and
the image display portion displays the component image designated by the template data and an image represented by the image data, which are merged with each other.

4. The image display device according to claim 3, wherein the identifier is a reduced image corresponding to an image represented by the data of the first kind.

5. The image display device according to claim 1, wherein the data of the first kind and the data of the second kind are stored in files which are independent of each other.

6. The image display device according to claim 5, wherein information capable of specifying the file storing the data of the second kind is stored in the file storing the data of the first kind so that the data of the second kind are related to the data of the first kind.

7. The image display device according to claim 1, further comprising a first instruction accepting portion for accepting an instruction for displaying an image,
the image display portion displaying the image when accepting the selection of the identifier by the selection accepting portion and then accepting the instruction for displaying the image by the first instruction accepting portion.

8. The image display device according to claim 1, further comprising a retrieving portion for retrieving the data of the first kind from a storage medium, and a correspondence information creating portion for deciding whether or not information specifying the data of the second kind is stored in a file storing the data of the first kind retrieved by the retrieving portion and creating information about a correspondence of the data of the first kind to the data of the second kind based on a result of the decision,
the identifier display portion referring to the information about the correspondence.

9. The image display device according to claim 1, further comprising a correspondence information creating portion for creating information about a correspondence of the data of the first kind to the data of the second kind when a removable storage medium is connected, the identifier display portion referring to the information about the correspondence.

10. A printer comprising:
the image display device according to claim 1; and
an image printing portion for printing an image on a printing medium based on the data of the first kind which are selected by the selection accepting portion and to which the data of the second kind are related and the data of the second kind which are related to the data of the first kind.

11. The printer according to claim 10, further comprising a second instruction accepting portion for accepting an instruction for printing the image,
the image printing portion printing the image when accepting the selection of the identifier by the selection accepting portion and then accepting the instruction for printing the image by the second instruction accepting portion.

12. An image display method comprising:
an identifier display step of displaying, on a screen, an identifier corresponding to data of a first kind to which data of a second kind are related and an identifier corresponding to the data of the first kind to which the data of the second kind are not related to be distinguished one from another;
a selection accepting step of accepting a selection of the identifier displayed at the identifier display step; and
an image display step of displaying an image on the screen based on the data of the first kind corresponding to the identifier selected at the selection accepting step and the data of the second kind which are related to the data of the first kind.

13. An image display program product for causing a computer to function as:
an identifier display portion for displaying, on a screen, an identifier corresponding to data of a first kind to which data of a second kind are related and an identifier corresponding to the data of the first kind to which the data of the second kind are not related to be distinguished one from another;
a selection accepting portion for accepting a selection of the identifier displayed by the identifier display portion; and
an image display portion for displaying an image on the screen based on the data of the first kind corresponding to the identifier selected by the selection accepting portion and the data of the second kind which are related to the data of the first kind.
